(19) United States
(12) Patent Application Publication
(10) Pub. No.: US 2026/0130040 A1
(43) Pub. Date: May 7, 2026

(54) ON-DEMAND FORMATION OF LEWIS BASE MOLECULES FOR EFFICIENT AND STABLE PEROVSKITE SOLAR CELLS

(71) Applicant: The University of Toledo, Toledo, OH (US)

(72) Inventors: Yanfa Yan, Toledo, OH (US); Sheng Fu, Toledo, OH (US)

(21) Appl. No.: 19/379,203

(22) Filed: Nov. 4, 2025

Related U.S. Application Data
(60) Provisional application No. 63/715,939, filed on Nov. 4, 2024.

(51) Int. Cl. H10K 30/50; C01G 21/16; H10K 85/50

(52) U.S. Cl. CPC H10K 30/50; C01G 21/16; H10K 85/50; C01P 2002/34; C01P 2002/74; C01P 2006/40

(57) ABSTRACT

The on-demand formation of Lewis base molecules for fabricating efficient and stable formamidinium lead iodide (FAPbI₃)-based perovskite solar cells (PSCs). Semicarbazide hydrochloride (SECl) is incorporated as an additive in the perovskite precursor, which deprotonates to form semicarbazide (SE) molecules when needed to stabilize the intermediate 𝛿 phase. SE molecules protonate again to form SECl salt when they must be removed rapidly to accelerate the transition from the intermediate 𝛿 phase to the photovoltaic 𝛼 phase, leading to high film quality and homogeneous vertical distributions of A-site cations.

### CROSS-REFERENCE TO RELATED APPLICATIONS

This application is a nonprovisional patent application that makes a priority claim to U.S. Provisional Application No. 63/715,939.

### STATEMENT REGARDING FEDERALLY SPONSORED RESEARCH

This invention was made with government support under DE-EE0008753 awarded by the Department of Energy and under DE-EE0008970 awarded by the Department of Energy. The government has certain rights in the invention.

### FIELD

The application relates to the manufacture of perovskite solar cells and, more particularly, to additives for perovskite precursor solutions that are provided for the on-demand formation of Lewis base molecules.

### BACKGROUND

The state-of-the-art perovskite solar cells (PSCs) and modules presently employ formamidinium lead iodide (FAPbI₃)-based absorbers.

A small amount of inorganic A-site cations with smaller ionic sizes, such as cesium (Cs) and rubidium (Rb), are commonly added to improve the device stability and passivate the perovskite films, respectively.

The manufacture of FAPbI₃ and other lead halide-based PSCs generally involves the steps of preparing a precursor solution, depositing the precursor solution onto a substrate, and then performing thermal annealing to promote crystallization and solvent evaporation. Within this context, skilled artisans will appreciate that the terms “α-phase” and “δ-phase” refer to distinct crystallographic phases of the perovskite material. The α-phase is typically orthorhombic and has a well-defined crystal lattice that is conducive to efficient charge transport, making it desirable for photovoltaic applications. The δ-phase is often trigonal in structure and tends to be more disordered compared to the α-phase; it exhibits inferior performance in photovoltaic applications compared to the α-phase.

To form high-quality FAPbI₃ photovoltaic absorber films, a lower annealing temperature (less than 150 °C) is desirable to avoid the loss of volatile species such as iodide(I⁻) and formamidinium (FA⁺). However, at lower annealing temperatures FAPbI₃ films tend to crystalize into the undesirable non-photovoltaic δ-phase; FAPbI₃ films only crystalize to the desirable photovoltaic α-phase at annealing temperatures higher than 170 °C.

Typically, a significant amount of methylammonium chloride (MACl) is added to promote the formation of the photovoltaic α-phase. This is undesirable since it lead to excessive material usage and because the incorporation of MA molecules into the perovskite lattice introduces a source of structural instability. It is now widely accepted that the fabrication processes must be MA-free to achieve long term cell stability.

The photovoltaic FAPbI₃-based α-phase typically forms through the transition from an intermediate δ phase to the photovoltaic α phase when no or a small amount of MACl additive is used. However, FAPbI₃-based films fabricated by the MA-free method often exhibit two issues: (1) relatively low film quality (e.g., small grain sizes and voids at the buried interface); and (2) inhomogeneous vertical distributions of the A-site cations due to the different crystallization rates of all inorganic perovskite phases, such as CsPbI₃ and RbPbI₃, and FAPbI₃. Inhomogeneity of the A-site cations can result in poorer power conversion efficiency (PCE) and stability of PSCs.

Accordingly those skilled in the art continue with research and development efforts in the field of lead halide perovskites.

### SUMMARY OF THE INVENTION

The present invention relates to additives for perovskite precursor solutions, and to methods of fabricating lead halide perovskite films using such additives. The invention provides an additive that includes a halide salt of a protonated Lewis base that is capable of reversible acid–base dissociation. The Lewis base component of the additive is capable of coordinating with lead, thereby influencing the crystallization and stability of the perovskite material.

In certain embodiments, the halide salt comprises a hydrazide compound, such as semicarbazide and/or carbonohydrazide, and more particularly semicarbazide hydrochloride (SECl) and carbonohydrazide hydrochloride salts. The additive may be incorporated into perovskite precursor solutions that include a lead halide precursor material (e.g., formamidinium lead iodide, FAPbI₃) and a solvent in which the halide salt is soluble, such as dimethylformamide (DMF), dimethyl sulfoxide (DMSO), or mixtures thereof. The additive may be present at a molar ratio ranging from 0.1% to 2%, preferably about 1%, relative to the amount of lead halide precursor material. The halide salt preferably exhibits an acid dissociation constant (pKa) of no greater than 4 in solution, and the solvent(s) used preferably coordinate with lead less strongly than the Lewis base component of the additive.

The invention further provides a method of fabricating lead halide perovskites using such precursor solutions. In the method, a precursor solution containing a lead halide precursor material, the halide salt additive, and a solvent is deposited on a substrate. Upon deposition and mild thermal annealing, at least part of the halide salt dissociates, producing a deprotonated Lewis base that coordinates with lead ions, thereby stabilizing an intermediate δ phase of the perovskite material. Subsequent solvent removal—by heating, anti-solvent dripping, or a combination thereof—causes re- protonation of the Lewis base and reformation of the halide salt, facilitating conversion to the desired perovskite phase. The fabrication can be performed at relatively low temperatures, e.g., below 150 °C, enabling mild processing conditions suitable for temperature-sensitive substrates.

In particular embodiments, semicarbazide hydrochloride (SECl) serves as the additive. During annealing, SECl undergoes partial dissociation into semicarbazide (SE) and hydrochloric acid (HCl), allowing SE to coordinate with lead in the intermediate δ phase. As solvent is removed, SE is re-protonated to regenerate SECl. The solvent removal may involve sequential steps, such as anti-solvent dripping to extract DMF followed by thermal annealing to remove DMSO, with at least 95% of the solvent being removed within 15 minutes at temperatures below 150 °C.

Through the use of such reversible halide salt additives, the invention enables improved control over perovskite crystallization and enhanced phase stability under mild processing conditions.

### BRIEF DESCRIPTION OF THE DRAWINGS

FIG. 1 is a diagram showing a reversible chemical reaction involving semicarbazide hydrochloride and its decomposition to semicarbazide and hydrocholoric acid in the presence of dimethylformamide;

FIG. 2 is a XRD pattern of the Ref FAPbI₃ film before annealing;

FIG. 3 is a XRD pattern of the Ref FAPbI₃ film after annealing;

FIG. 4 is a XRD pattern of the Target FAPbI₃ film before annealing;

FIG. 5 is a XRD pattern of the Target FAPbI₃ film after annealing;

FIG. 6 is a EXAFS spectra obtained from the Ref and Target FAPbI₃films;

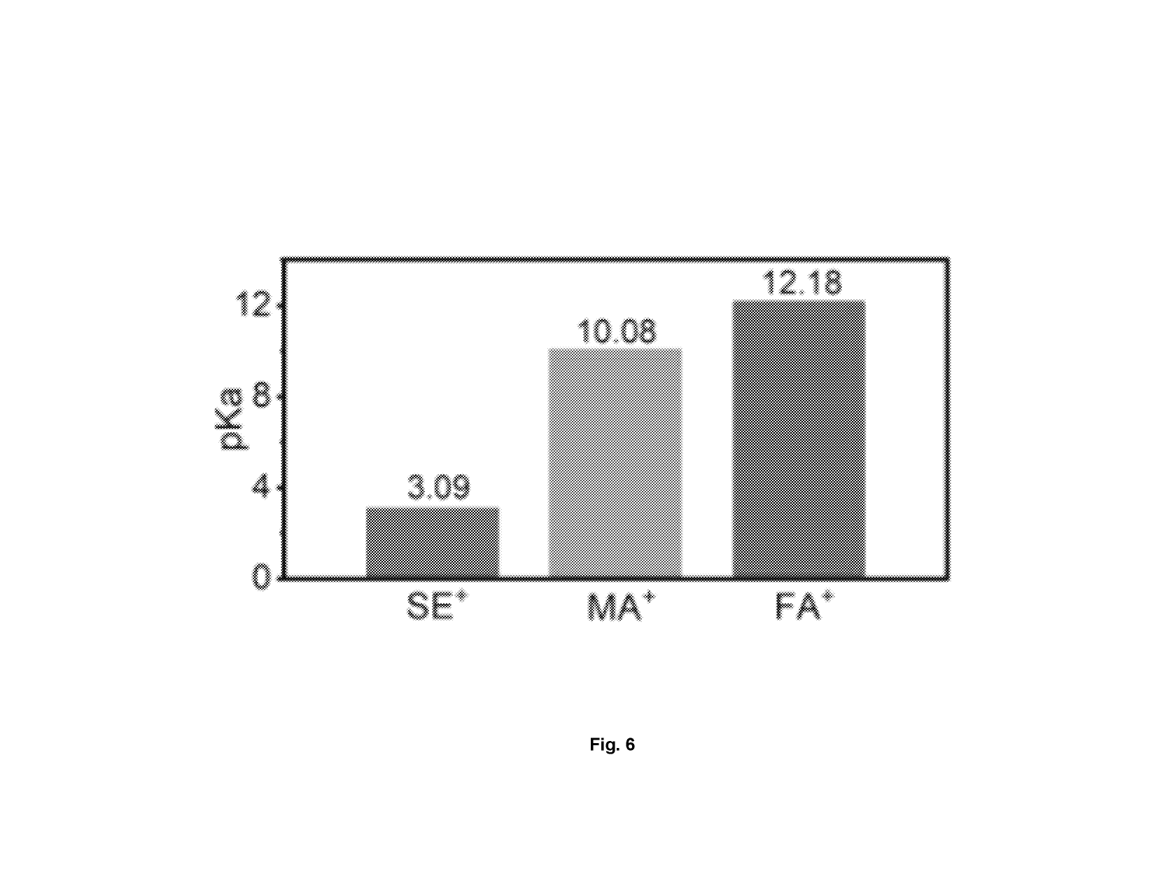

FIG. 7 is an in-situ XRD patterns of the Ref and Target FAPbI₃films after antisolvent treatments;

FIG. 8 is a series of SEM images of the Ref and Target FAPbI₃films before and after annealing;

FIG. 9 is a PL curve of the Ref and Target films;

FIG. 10 is a J-V curve of the champion Ref and Target PSCs;

FIG. 11 is an EQE spectra of the champion Ref and Target PSCs;

FIG. 12 is statistics diagrams of V_{oc}s and PCEs of the Ref and Target PSCs;

FIG. 13 is a diagram of PCE and V_{oc} deficit of the reported high-efficiency inverted PSCs;

FIG. 14 is a graph of MPPT stability of the PSCs at 85 °C;

FIG. 15 is a J-V curve of a large area device;

FIG. 16 is a J-V curve of a minimodule; and

FIG. 17 is a graph of MPPT stability results.

### DETAILED DESCRIPTION

The following detailed description refers to the accompanying drawings, which illustrate specific examples described by the disclosure. Other examples having different structures and operations may still fall within the scope of the present disclosure. Like reference numerals may refer to the same feature, element, or component in the different drawings.

Illustrative, non-exhaustive examples of the subject matter according to the present disclosure are provided below. Reference herein to “example” means that one or more feature, structure, element, component, characteristic and/or operational step described in connection with the example is included in at least one embodiment and/or implementation of the subject matter according to the present disclosure. Thus, the phrase “an example” and similar language throughout the present disclosure may, but do not necessarily, refer to the same example. Further, the subject matter characterizing any one example may, but does not necessarily, include the subject matter characterizing any other example.

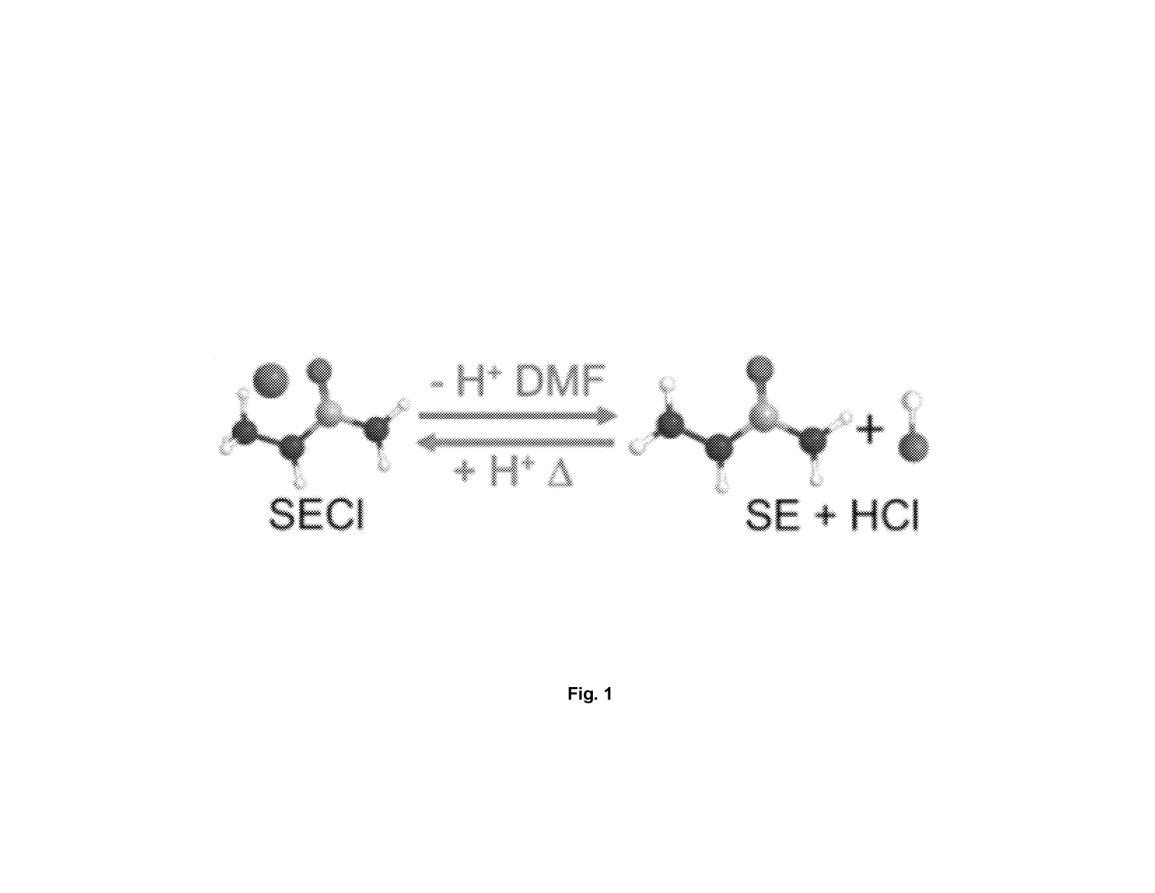

The present invention relates to a strategy for the on-demand formation of Lewis molecules to mitigate the issues mentioned above. More specifically, the invention utilizes semicarbazide hydrochloride (SECl) salt as an additive in lead halide-based precursor formulations (including, but not limited to, FAPbI₃-based precursor solutions), in which the SECl salt undergoes deprotonation to generate semicarbazide (SE) Lewis base molecules in situ (FIG. 1).

Perovskite precursors employ organic polar solvents such as dimethylformamide (DMF) and dimethyl sulfoxide (DMSO), both of which function as Lewis base molecules. These molecules coordinate with Pb ions on the surfaces of the δ phase after solvent removal by anti-solvent dripping (dripping an anti-solvent onto a precursor film) or gas blowing (controlled stream of inert gas directed onto or into a liquid sample). Rapidly removing these molecules is necessary for accelerating the phase transition of FAPbI₃ from the δ phase to the α-phase, which was found to be helpful in avoiding phase separation. Solvent molecules with a strong coordination strength are favorable for stabilizing the δ phase, but they are not desirable for rapid phase transition due to being slower to extract. On the other hand, solvent molecules with weaker coordination with Pb ions can be extracted more easily, but they are less preferred for stabilizing the δ phase.

The semicarbazide molecules coordinate with Pb ions more strongly than the solvent molecules, thereby stabilizing the intermediate δ phase. When no longer needed – i.e., when they must be removed from the intermediate phase to promote the transition from the δ phase to the α phase – the semicarbazide molecules protonate again and convert back to SECl salt. The re-protonation occurres automatically upon annealing since it depends on solvent evaporation, which can be very rapid. Therefore, the on-demand formation of Lewis base semicarbaize molecules reduces the difference in the crystallization rates for all inorganic perovskites and FAPbI₃ perovskite, leading to advantages such as homogeneous vertical distributions of A-site cations, larger grain size, and reduced density of voids at the buried interfaces. The results were confirmed by detailed characterizations, including time-dependent X-ray diffraction (XRD) and density functional theory (DFT) calculations.

The strategy of on-demand formation of Lewis molecules demonstrated significant benefits on the device performance of PSCs. The PSCs using SECl additive achieved a champion PCE of 26.12% (certified PCE 24.65%), outperforming the PSCs without SECl additive, which exhibited a champion PCE of 23.04%. As used herein, the term “Champion PCE” or “Champion Power Conversion Efficiency” refers to the best-performing (highest efficiency) cell out of the samples tested and represents the peak performance of a cell under optimal conditions. As discussed in greater detail below, the devices with SECl additive maintained over 96% of their efficiency for 1000 hours under maximum power point tracking at 85 °C. The strategy also showed good scalability, demonstrating champion PCEs of 24.41% and 21.47% for cells with a 1.2-cm² area and minimodules with an 11.52 cm²aperture area , respectively. The extent to which use of the SECl additive was able to improve the performance of lead halide-based PSCs is considered unexpected.

### Influence on Phase Transition in FAPbI3 Films

Experiments were performed to examine the influence of SECl additive on the phase transition of pure FAPbI₃ thin films (i.e., composed solely or predominately of the compound FAPbI3 without inclusion of other cation or anion such as Cs⁺, MA⁺, or Br⁻). These experiments utilized the solvents DMF and DMSO as the reference for comparison. Since DMF is much more volatile and has a weaker coordination strength with Pb ions than DMSO, most DMF solvents will be rapidly removed during the anti-solvent dripping process, leaving a significant amount of residual DMSO in the film.

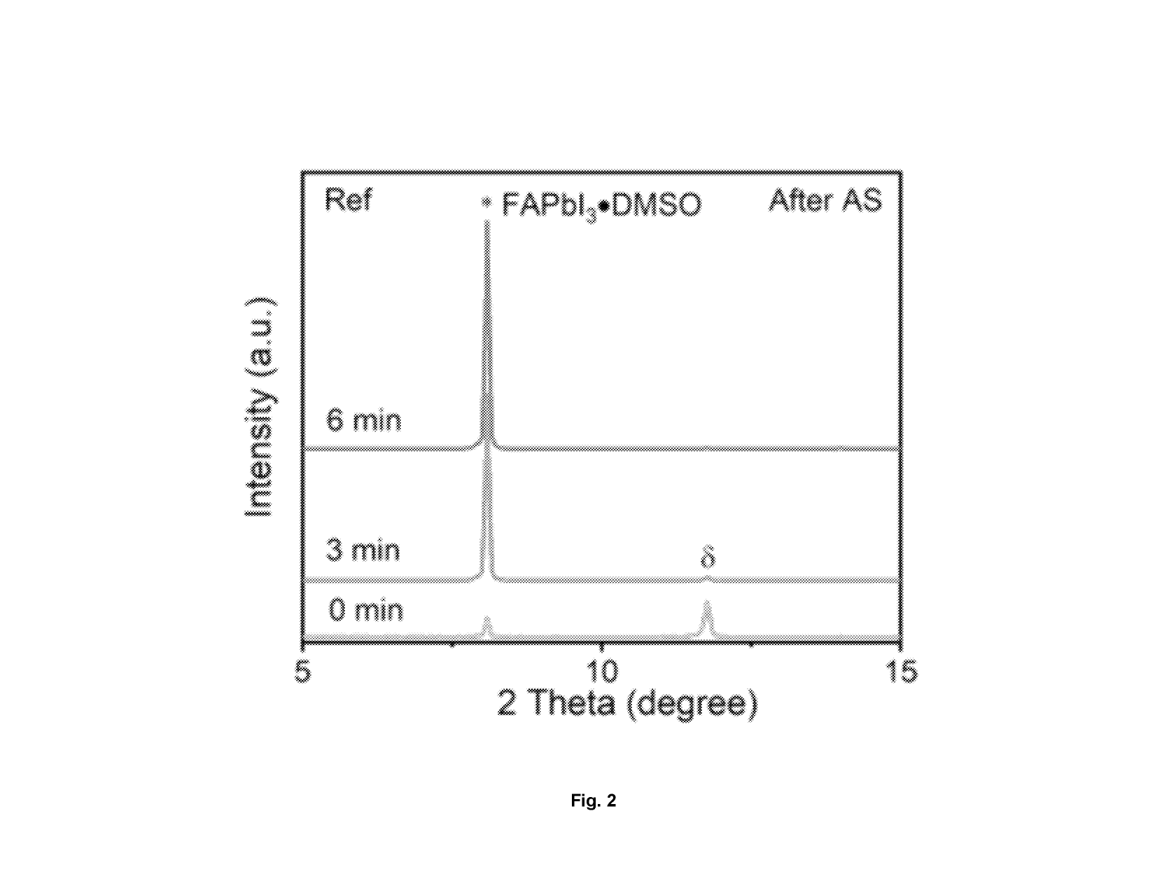

As seen from XRD patterns shown in FIG. 2, the intermediate δ phase (as revealed by the XRD peak at ~12.5 °) first formed after the anti-solvent dripping process and then was converted to a FAPbI₃•DMSO intermediate phase by the residual DMSO molecules as indicated by the increased intensity of the x-ray diffraction (XRD) peak at 8.1 °. It is contemplated that the crystal structure of the FAPbI₃•DMSO intermediate phase could be attributed to the diffusion of DMSO molecules into the δ phase. DMSO molecules coordinate with Pb ions on the surfaces of the FAPbI₃•DMSO intermediate phase, but inside, they couple with FA ions through weak Coulombic attraction due to the unpaired electrons at the oxygen atoms in the DMSO molecules. The calculated binding energy between DMSO and FA ions is 0.3 eV. The lattice constants are a=b=8.66 Å, c=7.90 Å, for the intermediate δ phase but are expanded to a=b=12.20 Å, c=7.44 Å for the FAPbI₃•DMSO intermediate phase.

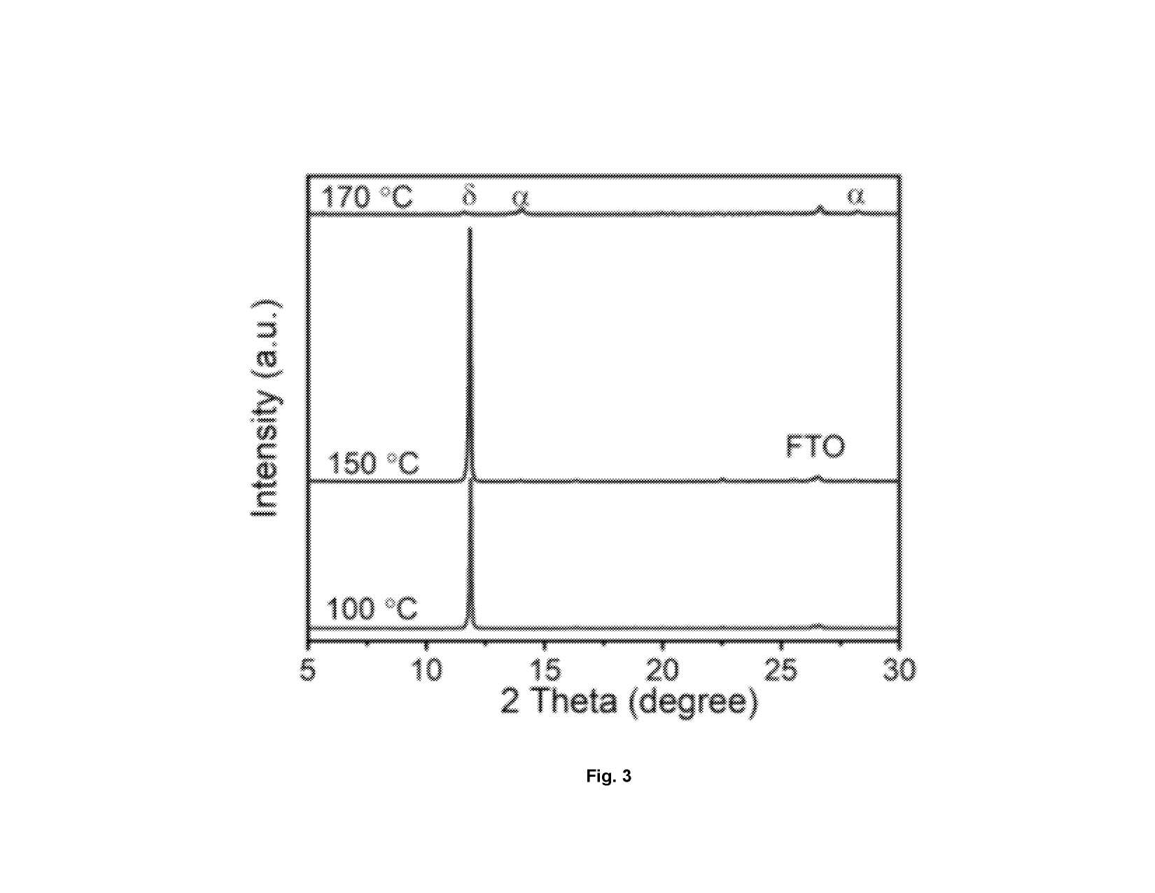

Upon annealing at 100 °C, the FAPbI₃•DMSO intermediate phase was first converted back to the δ phase by releasing DMSO molecules inside. The DMSO molecules coordinated with Pb ions on the surface to stabilize the δ phase, making the removal of these molecules more difficult. The FAPbI₃ intermediate δ phase was eventually converted to the photovoltaic α phase when these DMSO molecules were removed after annealing at a higher temperature, 170 °C, to break the DMSO-Pb coordination. The resulting FAPbI₃ films showed poor quality, as revealed by the XRD (FIG. 3).

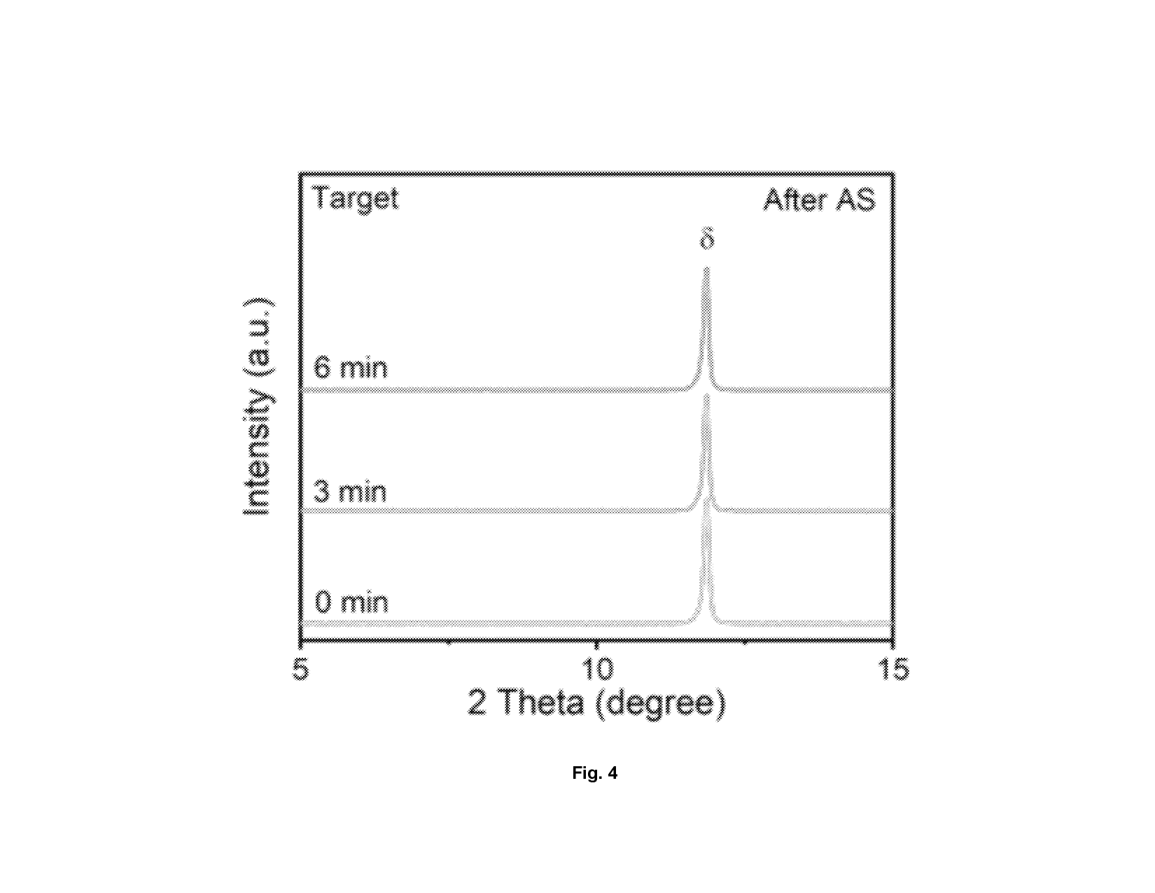

Incorporating a small amount SECl additive (1%, molar ratio relative to the quantity of FAPbI₃) significantly changed the growth process of the FAPbI₃ thin films. As seen from the XRD patterns in FIG. 4, the intermediate δ phase formed and remained even though the same amount of DMSO was used in the precursor. SECl features a low acid dissociation constant (pKa), suggesting that the SE+ cations can be spontaneously deprotonated into SE in DMF and DMSO based precursors.

DFT calculation showed that the SE molecules coordinate with Pb ions on the surface of the intermediate δ phase more strongly than the DMSO molecules. With the SECl additive, the surface of the intermediate δ phase was mainly coordinated by SE molecules. Without the SECl additive, the Pb-O bond length is 1.75 Å, while it is shortened to 1.68 Å in the presence of the SECl additive, confirming that SE molecules preferentially coordinate with Pb ions. The stronger coordination enhanced the stability of the δ phase, preventing DMSO molecules from diffusion into the δ phase to convert it into the FAPbI₃•DMSO intermediate phase, consistent with the observation that the intermediate δ phase remained after anti-solvent dripping.

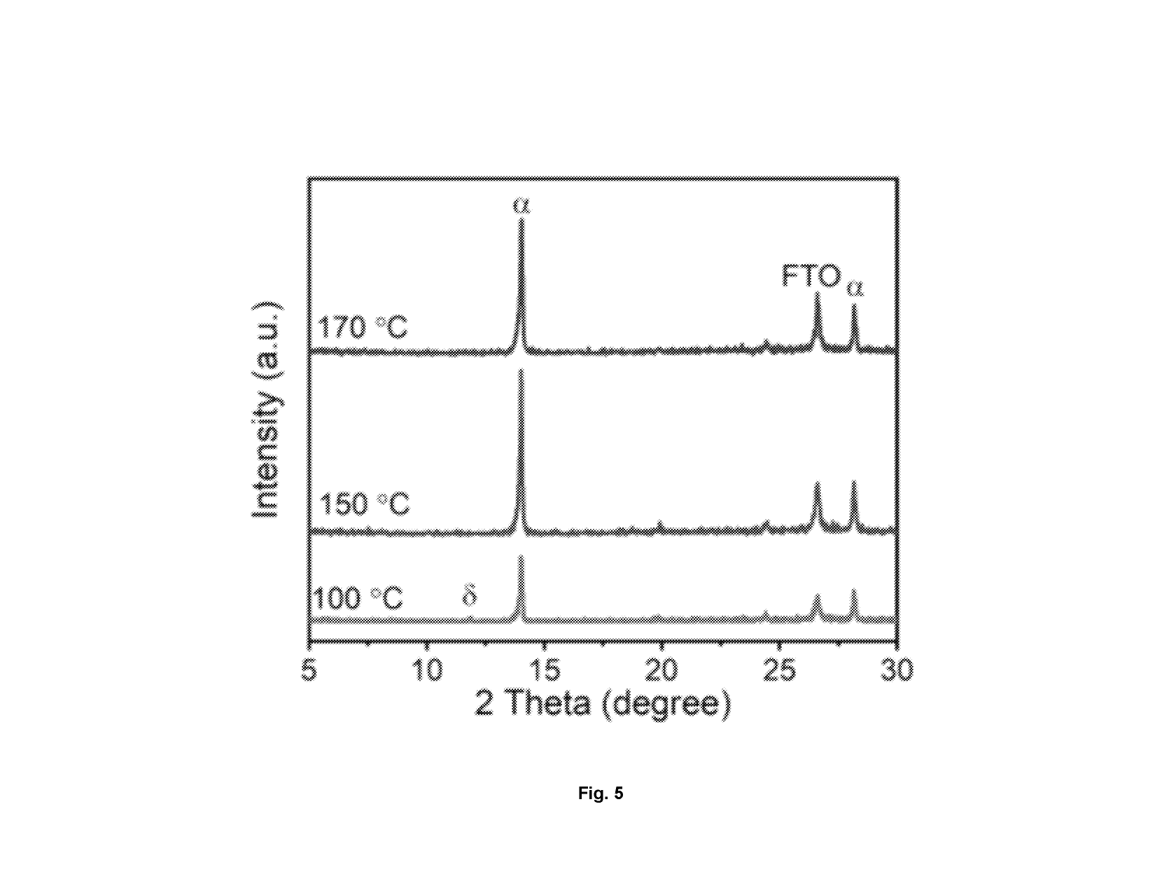

Upon annealing, the remaining uncoordinated DMF and DMSO evaporated quickly, forcing the SE molecules to protonate back to SECl salt very rapidly. This process easily removed the SE molecules from the surface of the intermediate δ phase, accelerating the transition from the δ phase to the α phase. As seen in FIG. 5, the phase transition occurred at temperatures as low as 100 °C. It is noted that the on-demand formation of SE molecules is critical for enabling the rapid transition from the δ phase to the α phase.

If pre-synthesized base molecules were used as additives, they would coordinate the Pb ions on the surface of the δ phase. Removing these molecules would require higher annealing temperatures. To confirm this, carbonohydrazide (CBH) molecules were tested as an additive. CHB molecules have even higher coordination strength than SE molecules, stabilizing the δ intermediate phase even more. The stronger coordination energy made CBH molecules more difficult to remove during the annealing. As a result, some δ phase remained after annealing at 170 °C.

The reversible re-protonation process depends only on the concentration of the uncoordinated solvents that can be removed much more easily upon annealing, enabling the phase transition at lower temperatures. CBHCl salt was also used as the additive, and similar results have been obtained. Therefore, the on-demand formation of base molecules through deprotonation and re-protonation of Lewis base molecule halide salt provides an excellent strategy to accelerate the transition from the δ phase to the α phase for FAPbI₃. This can reduce the difference in crystallization rates between all inorganic perovskites and FAPbI₃ perovskite, promoting the homogeneous vertical distribution of A-site cations.

### Effects on the Vertical Distribution of Inorganic A-site Cations

Experiments were performed to examine the beneficial effects of the on-demand formation of Lewis base molecules on the vertical homogeneous distribution of the A-site cations. A composition of FA_{0.85}MA_{0.05}Cs_{0.05}Rb_{0.05}PbI_{2.85}Br_{0.15} was utilized for these experiments. The composition is in the general form of perovskites ABX₃ where A is the monovalent cation, B is a divalent metal cation, and X is a halide anion, thus, the A-site cation is a mixture of FA⁺, MA⁺, Cs⁺, and RB⁺, the B-site cation is Pb2⁺, and the X-site anions are I⁻ and Br⁻.

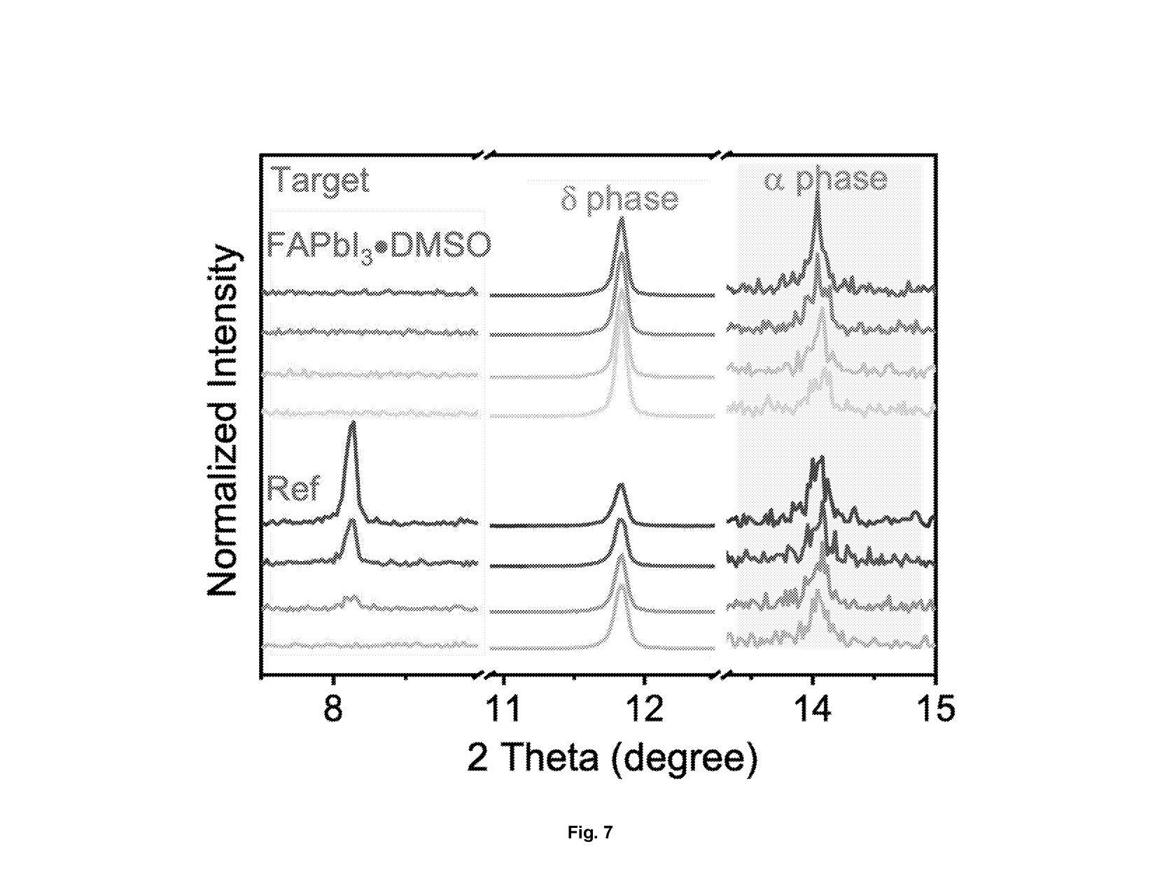

As an additive, RbPbI₃ provides excellent passivation to perovskite surfaces, interfaces, and grain boundaries. As shown in FIG. 7, FAPbI₃ films with 5% Cs and 5% Rb showed similar behavior as the pure FAPbI₃ film (which does not contain SECI additive) (referred to herein as “Ref”) after anti-solvent dripping; the intermediate δ phase first formed and then was converted into the FAPbI₃•DMSO phase. In contrast, in the film that did include SECI additive (referred to herein as “Target”) the intermediate δ phase formed and remained. The incorporation of Cs and Rb promoted the formation of a small amount of the α phase in films in both the Ref and Target samples due to the smaller ionic sizes of Cs and Rb (relative to FA).

In-situ GIWAXS (grazing incidence wide angle x-ray scattering) measurements were conducted to examine the phase formation dynamics of the perovskite films during annealing. It took 10 min to align the X-ray beam with samples before signal collection. The α phase continued to grow during the alignment. After the alignment, at which the time is set as t=0, the Ref film still showed strong FAPbI₃•DMSO peaks, but the Target film showed relatively weak signals for the δ phase. the signal of the δ phase in the Ref film disappeared after annealing for 7 min. In sharp contrast, the weak δ peaks disappeared within 2.5 min annealing in the Target film, revealing a much-accelerated phase transition that is approx. 64% faster.

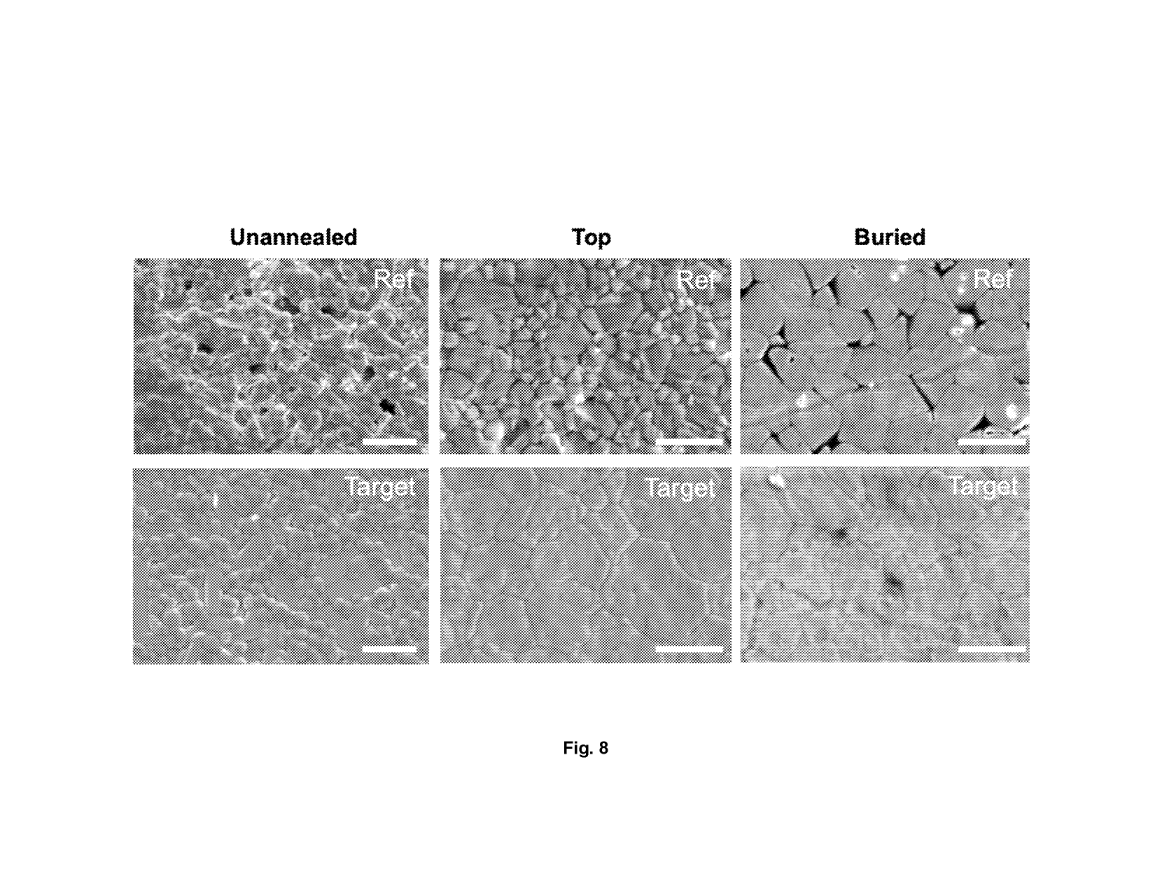

FIG. 8 shows top view scanning electronic microscopy (SEM) images of unannealed Ref (top row) and Target (bottom row) films. The Ref film showed an uneven morphology with large pinholes, while the Target film exhibited a homogeneous morphology (“Unannealed” column). After annealing, the Ref film showed a non-uniform grain feature , but the target film presented a much more uniform grain feature with larger grains (“Top” column). It is worth noting that the SEM images of the perovskite films peeled off from the substrates revealed that the Ref film presented a high density of voids at the buried interface (“Buried” column). In contrast, the Target film showed a nearly void-free morphology. It is contemplated that insufficient removal of DMSO molecules lmay be responsible for the voids at the buried surface during annealing in the Ref film. The residual DMSO molecules may be attributed to their coordination with Pb ions on the surfaces of the δ and α phases. In the Target film, fewer DMSO molecules can coordinate with Pb ions since SE molecules preferentially coordinated with Pb ions.

The emission of DMSO molecules in the Ref and Target films was examined using temperature-resolved mass spectroscopy. An obvious DMSO emission was detected in the Ref film at 110 °C, but only a rather weak DMSO signal was detected in the Target film. The time-of-flight secondary ion mass spectroscopy (TOF-SIMS) measurement showed that while the Ref film showed a much higher Rb concentration near the buried interface, the Target film showed a rather homogeneous vertical distribution of Rb. The vertical distribution of FA cation was measured to reveal the distribution of Cs ions since Cs ions are typically incorporated in the FAPbI₃ lattice.

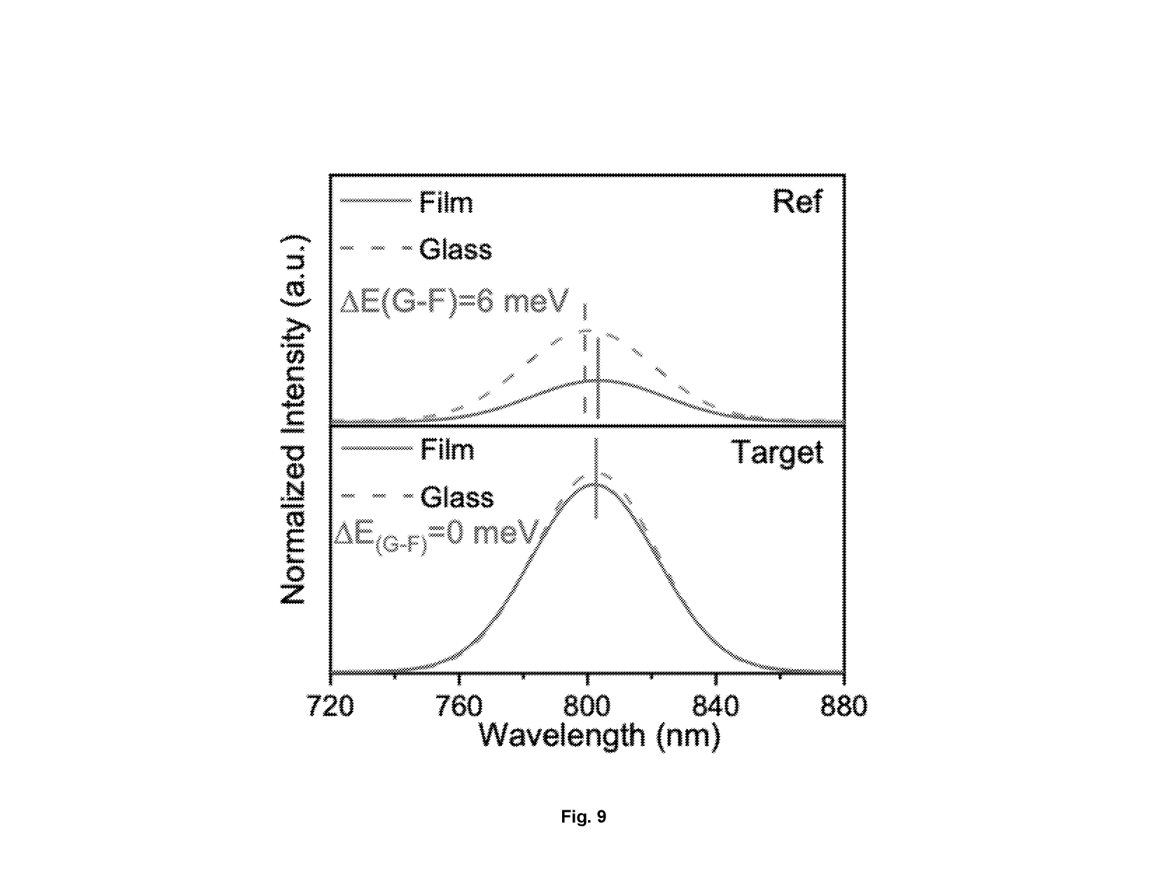

Photoluminescence (PL) emission was used to further confirm the vertical distributions of Cs. As shown in FIG. 9, PL peak with a 532nm laser excitation from the glass side showed a 6 meV higher energy than PL peak with the same laser but excited from the film side for Ref film. The higher PL energy indicates a higher Cs concentration, suggesting a higher Cs concentration near the buried interface than near the top surface. In contrast, the PL energy was identical when excited from either side of the Target film, confirming a homogeneous vertical distribution of Cs. The higher PL intensity observed in the Target film may be attributed to the larger grain size and homogeneous vertical distribution of RbPbI₃ that provided more effective passivation. Time-resolved PL spectra also showed longer carrier lifetimes in the Target film than in the Ref film. PL quantum efficiencies (PLQY) from the Ref and Target films were futher measured with excitation from both the glass side and the film side. I PLQY of the Ref film showed a higher value measured from the glass side than from the film side. This is consistent with the inhomogeneous vertical distribution of RbPbI₃ in the reference film, i.e., RbPbI₃ is preferentially distributed near the buried interface. In the Target film, the PLQY difference measured from the glass and film side is much smaller, consistent with the fact that RbPbI₃ is vertically distributed more uniformly. It is contemplated that mitigating voids at the buried interface enhances hole extract at the HTL/perovskite interface in the p-i-n solar cell, consistent with the transient photo-voltage (TPV) measurements of the bifacial PSCs fabricated with the Ref and Target perovskite films. The space-charge limited current (SCLC) curves with the fitted results showed that the trap density was reduced from 3.58×10¹⁵ in the Ref film to 2.15×10¹⁵ cm⁻³ in the Target film.

### Impacts on Device Performance

P-i-n inverted devices (i.e. solar cells having an inverted layer sequence—p-type / intrinsic / n-type—where charge extraction occurs in the reverse order compared to the conventional n–i–p structure) were fabricated with the configuration of FTO/MeO- 2PACZ/perovskite/C60/BCP/Ag, wherein “FTO” is Fluorine-doped Tin Oxide (transparent conductive oxide), “MeO-2PACZ” is 2-(3,6-dimethoxy-9H-carbazol-9-yl)ethyl)phosphonic acid (p-type layer), the perovskite was either the Ref or Target perovskite fims (i-type layer), “C60” is fullerene (n-type layer), “BCP” is bathocuproine (buffer/interfacial layer), and “Ag” is silver (metal electrode). The thickness of the perovskite films used was about 760nm.

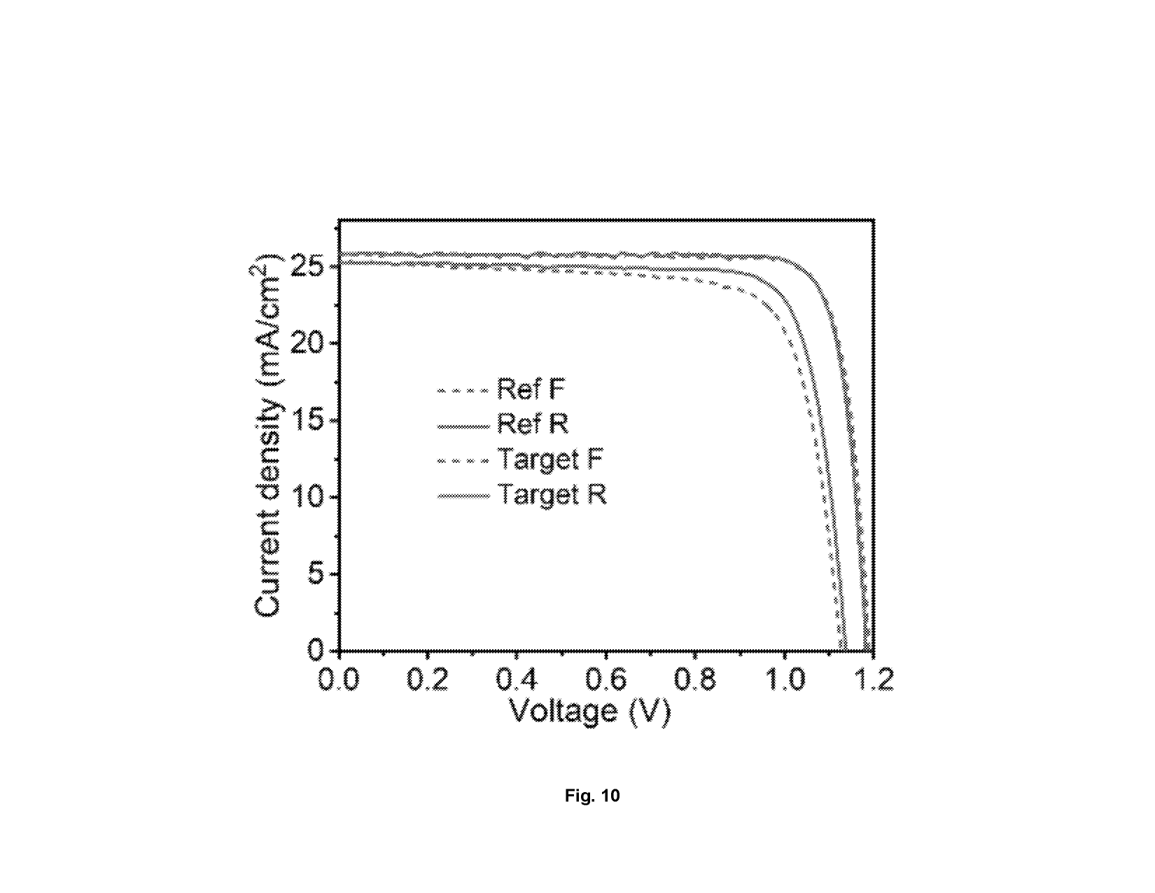

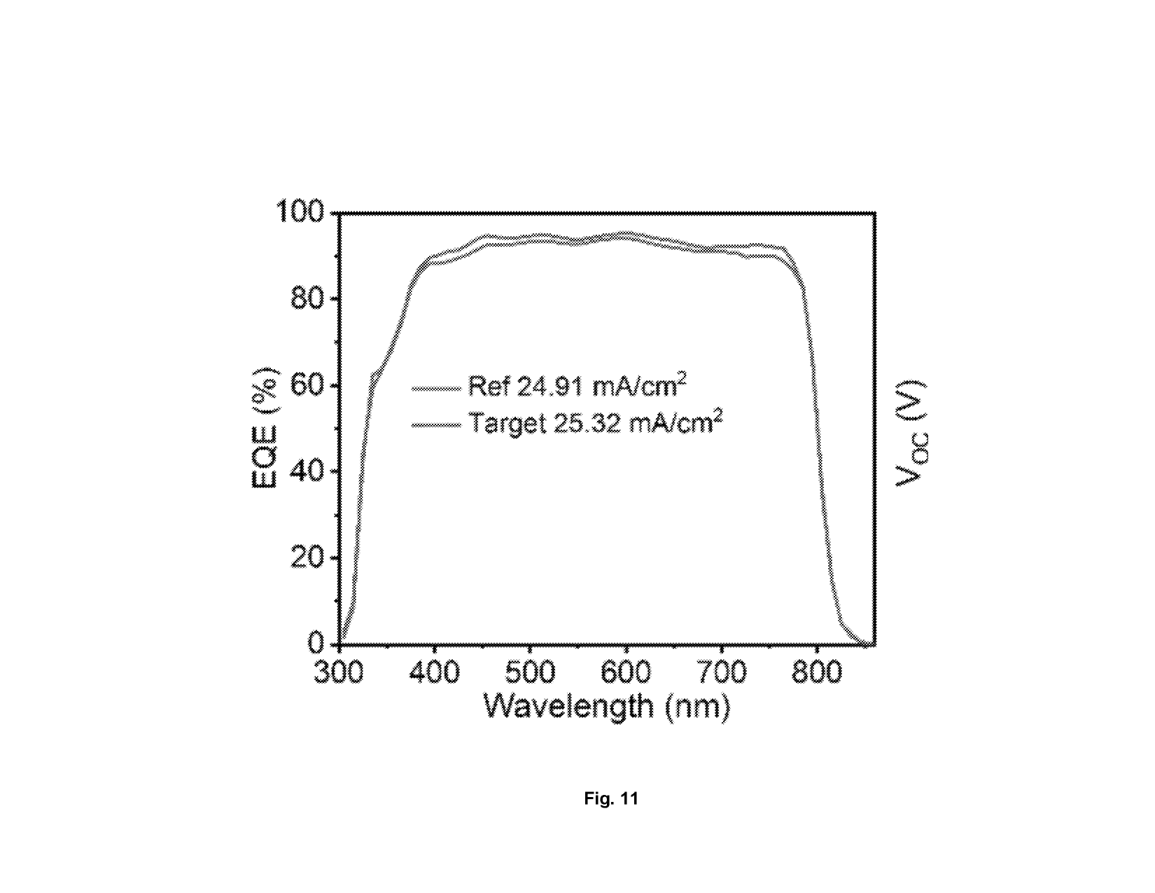

FIG. 10 shows the J-V curves of the champion devices using the Ref and Target perovskite films. The Ref device showed a power conversion efficiency (PCE) of 23.04% with an open-circuit voltage (V_{OC}) of 1.138 V, a short circuit current density (JSC) of 25.33mA/cm² and a fill factor (FF) of 79.96%. The Target device delivered a champion PCE of 26.12% with a V_{OC} of 1.185 V, a JSC of 25.78mA/cm², and a FF of 85.5%. The measured JSC of both devices matched well with the current densities integrated from external quantum efficiency spectra (EQE, FIG. 11), 24.91 and 25.32mA/cm² for the Ref and target devices, respectively. The Target device was measured at the National Renewable Energy Laboratory (NREL) and showed a certified quasi-steady-state efficiency of 24.65%, and a fast J-V scan efficiency of 25.32%. The more uniform vertical distribution of Rb, the lower density of voids at the buried interface, and the larger grain size seen in the Target film account for the improved performance of the Target devices.

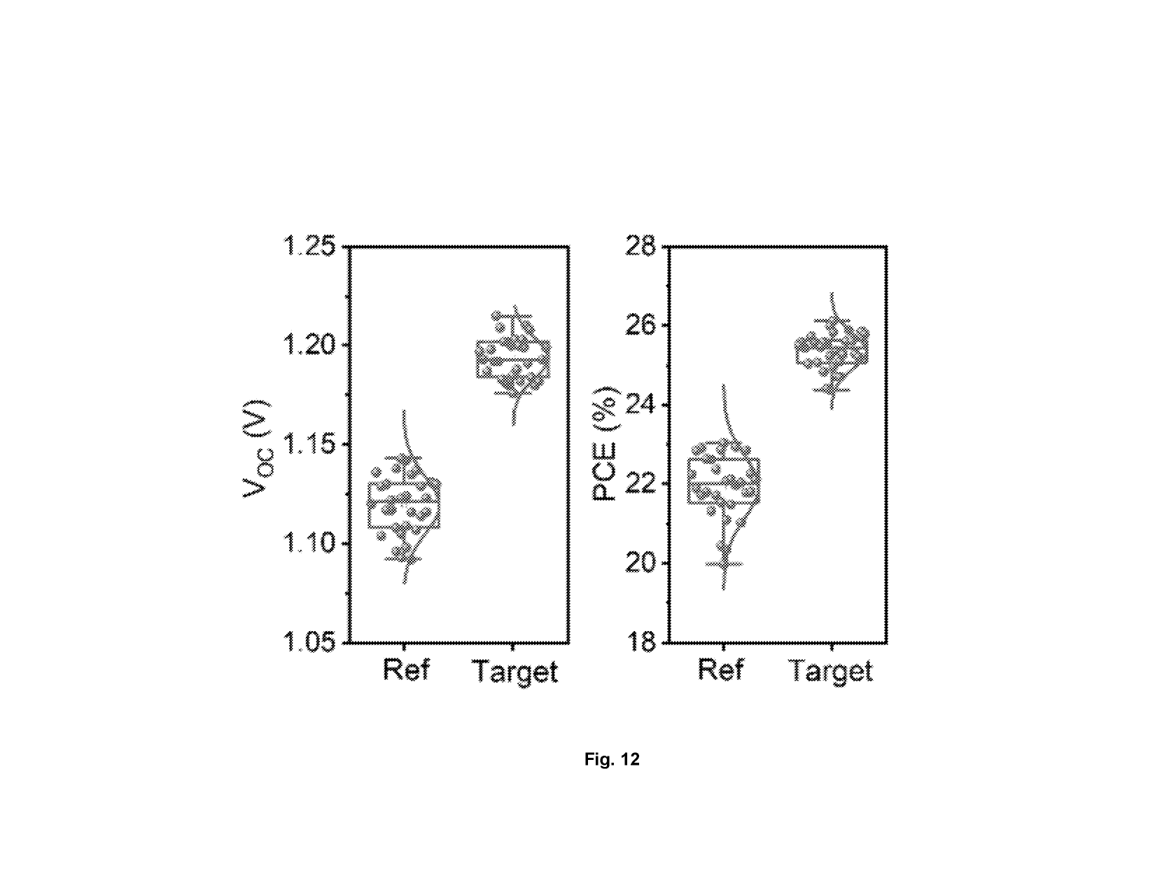

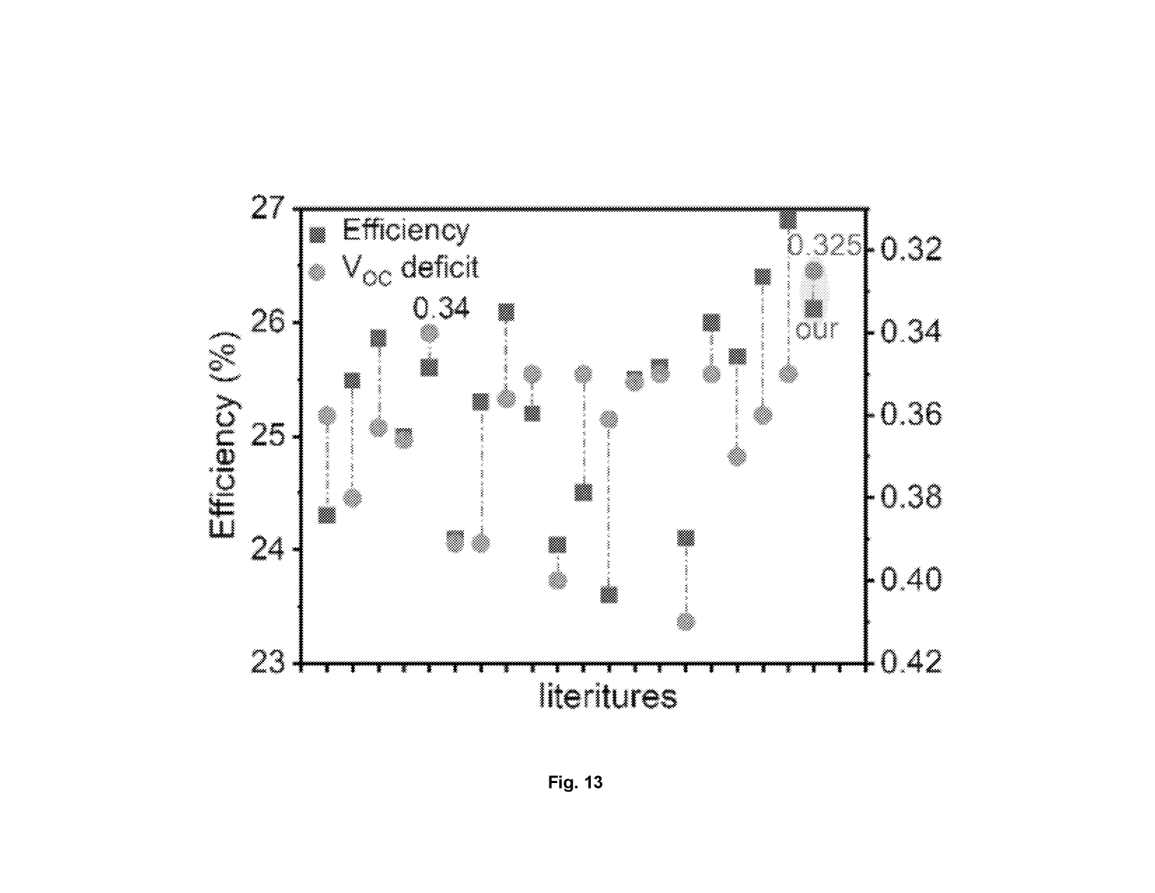

FIG. 12 presents the statistical distributions of V_{OC}s and PCEs of 30 individual Ref and Target devices. The Target devices showed clear improvements on all PV parameters over the Ref devices. Notably, the Target devices realized a champion V_{OC} of 1.215 V, with a V_{OC} deficit of 0.325 V, among the lowest reported V_{OC} deficits for inverted PSCs (FIG. 13). In addition, the strategy of on-demand formation of SE molecules to homogenize the vertical distribution of A-site cations can be applied to other perovskite compositions. Ref and Target devices using perovskite films with compositions of FA_{0.95}Cs_{0.05}PbI₃ and FA_{0.9}Cs_{0.1}PbI₃ were fabricated. Consistently, there were considerable improvements on the V_{OC} and FF, and, therefore, PCEs are observed in the Target devices.

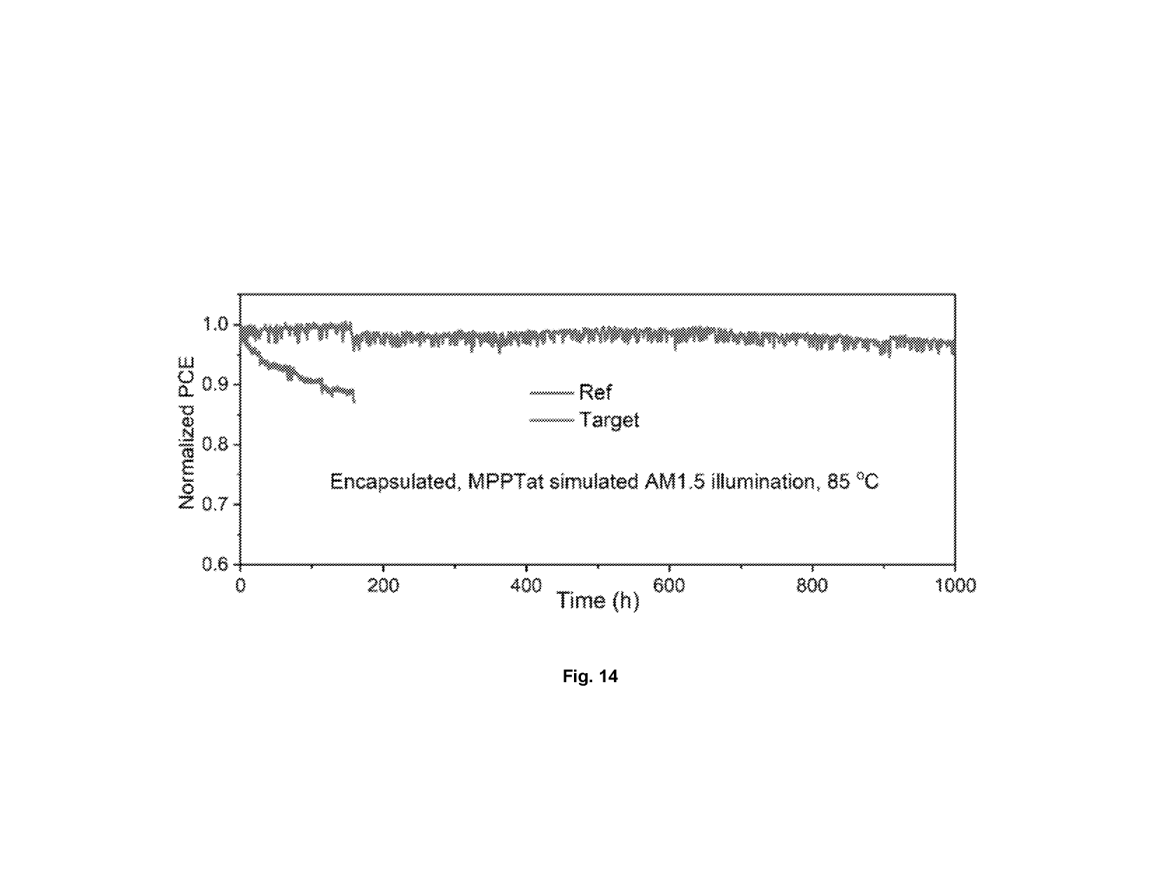

The stability of the encapsulated Ref and Target devices were measured under maximum power point tracking (MPPT) under continuous 0.9-sun illumination at room ambient. The Ref device showed a rapid degradation, i.e., the PCE decreased to below 80% of its initial efficiency after MPPT for 1000 h. On the other hand, the Target device remained at its initial PCE after MPPT for 3000 h. An encapsulated Target device also retained 96% of its initial efficiency after MPPT for 1000 h at 85 °C, as shown in FIG. 14. In comparison, the Ref device degraded to 90% of its initial PCE within 100 h MPPT under the same operation. The homogeneous vertical distribution of A-site cations in the Target device is the leading cause of the improved photo-thermal stability.

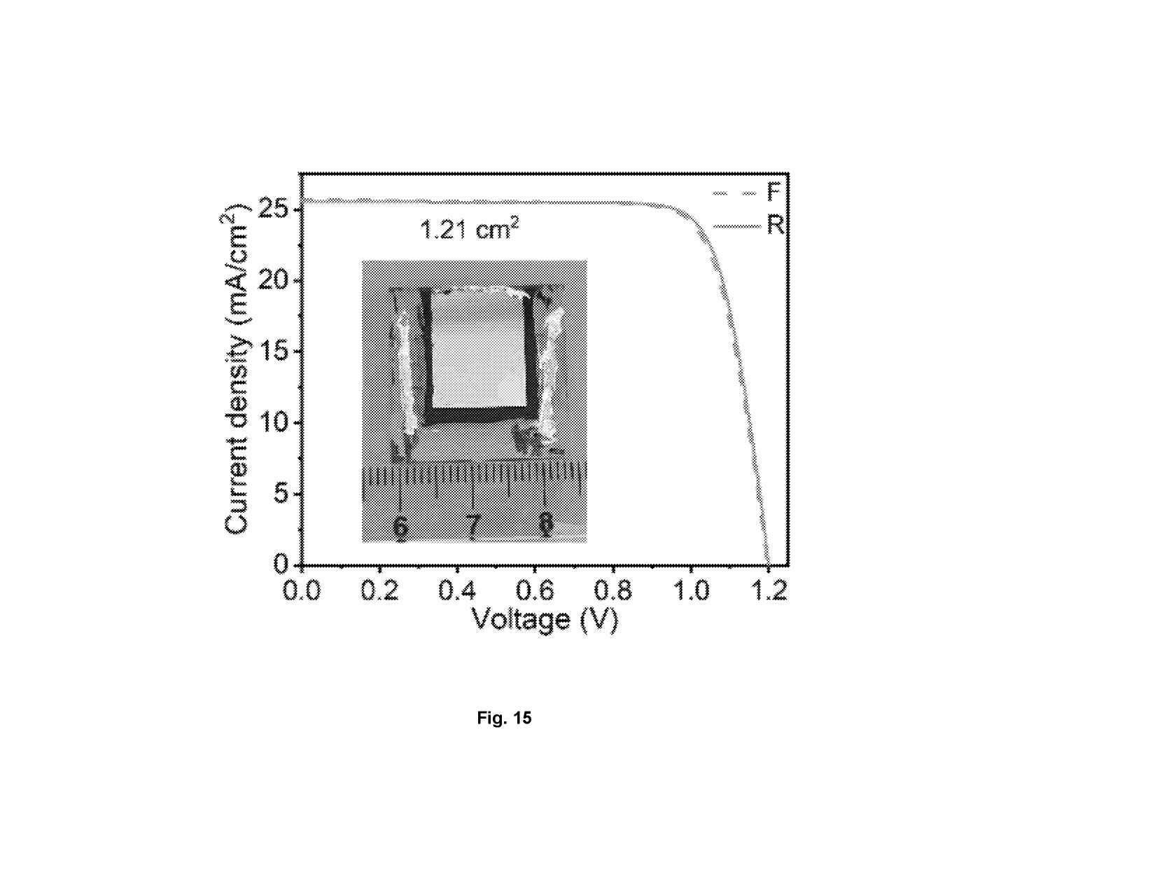

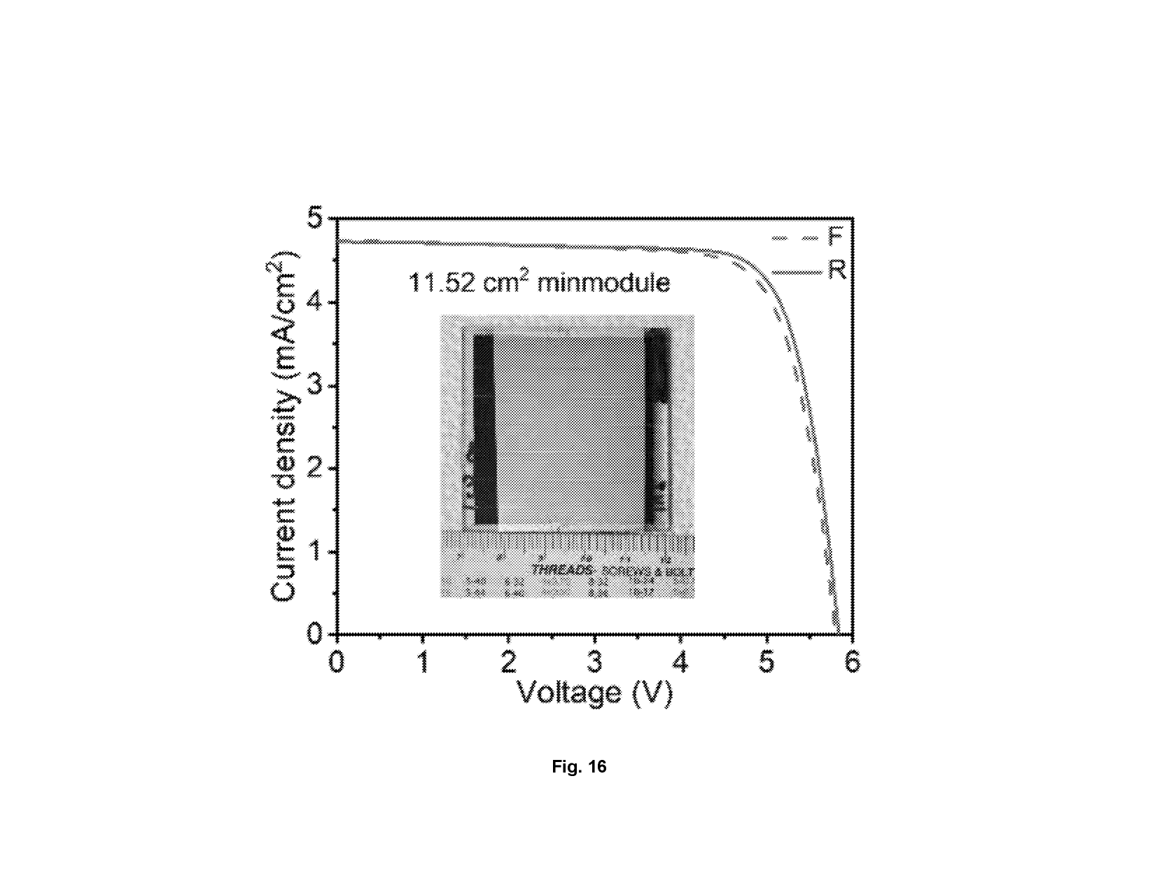

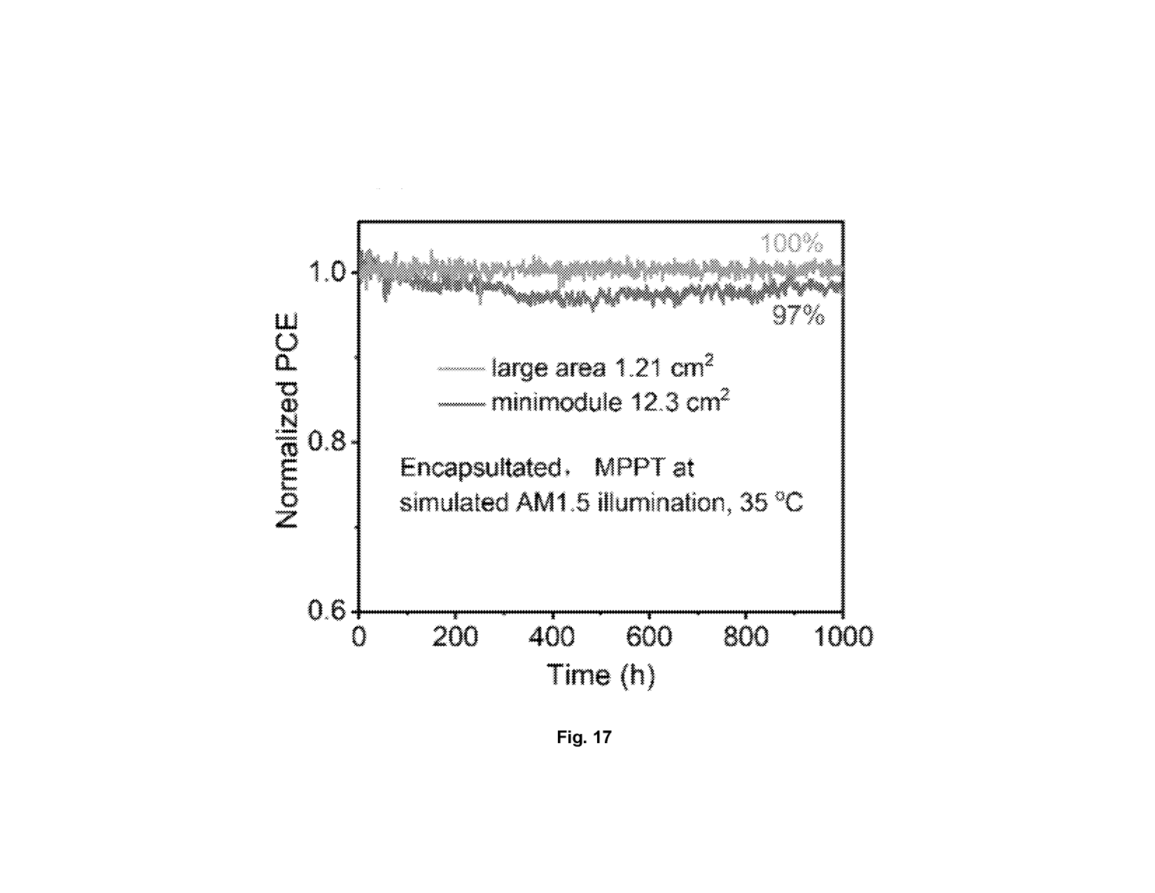

The improved film quality and homogeneous vertical inorganic A-site cation distribution also benefited the scalable fabrication of PSCs and minimodules. Large-area devices (1.21 cm²) were fabricated with the Target perovskite films. The large-area devices (FIG. 15) showed a champion PCE of 24.41% with a V_{OC} of 1.2 V. Furthermore, minimodules were fabricated on 5×5 cm² substrates with 5 subcells and a geometric fill factor of 94.8%. The minimodules displayed a good reproducibility, and the champion PCE of the minimodules with an aperture area of 11.52 cm² (FIG. 16) was 21.47% with a V_{OC} of 5.838 V, a JSC of 4.73mA/cm² and a FF of 77.8%. As shown in FIG. 17, the large-area device and minimodule maintained their initial PCEs after MPPT for 1000 h at room ambient.

Based on the above, it has been shown that the on-demand formation of Lewis base molecules is an excellent strategy to promote the transition from the δ phase to the α phase for lead halide perovskites, including FAPbI₃ perovskites. The deprotonation and re-protonation were the key mechanisms for the on-demand formation of SE molecules that accelerated the formation of α phase FAPbI₃ and avoided the preferential formation of CsPbI₃ and RbPbI₃ δ phase. Upon annealing, Rb ions diffused out to form RbPbI₃ at grain surfaces, i.e., film surface, grain boundaries, and buried interface, resulting in a homogeneous vertical distribution. The extent to which the vertical distribution of A-site cations was uniform, together with enlarged grain sizes, was unexpected and significantly improved the solar cell performance. The resulting PSCs demonstrated a champion efficiency of 26.1% with superior scalability and stability. The strategy presented herein represents a new approach to manipulate the phase transition and grain growth to produce high-quality FAPbI₃-based perovskite films and devices.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will fall within the spirit of the claimed invention. It is the intention, therefore, to limit the invention only as indicated by the scope of the claims.

What is claimed is:

1. An additive for perovskite precursor solutions that comprise a lead halide precursor material, the additive comprising:
a halide salt of a protonated Lewis base, wherein:
the halide salt is capable of reversible acid-base disassociation; and
the Lewis base is capable of coordinating with lead.

2. The additive of claim 1, wherein:
the halide salt comprises a hydrazide compound such as semicarbazide and/or carbonohydrazide.

3. The additive of claim 2, wherein:
the halide salt comprises at least one of semicarbazide hydrochloride (SECl) salt and carbonohydraxide hydrochloride salt.

4. A perovskite precursor solution comprising:
a lead halide precursor material;
the additive of claim 1; and
a solvent in which the halide salt is soluble.

5. The perovskite precursor solution of claim 4, wherein:
the lead halide precursor material comprises a lead iodide-based material such as formamidinium lead iodide (FAPbI3).

6. The perovskite precursor solution of claim 4, wherein:
the additive of claim 1 is provided at a molar ratio ranging from 0.1% to 2%, preferably about 1%, based on the amount of lead halide precursor material in the perovskite precursor solution.

7. The perovskite precursor solution of claim 4, wherein:
the halide salt of the additive of claim 1 has an acid dissociation constant (pKa) of no greater than 4 in solution.

8. The perovskite precursor solution of claim 4, wherein:
each solvent present in the perovskite precursor solution coordinates with lead less strongly than the Lewis base of the halide salt.

9. The perovskite precursor solution of claim 4, wherein:
the solvent comprises an organic polar solvent such as dimethylformamide (DMF), dimethyl sulfoxide (DMSO), and combinations thereof.

10. A method of fabricating lead halide perovskites, the method comprising the steps of:
depositing a precursor solution on a substrate, the precursor solution comprising:
a lead halide precursor material;
a halide salt of a protonated Lewis base that is capable of reversible acid–base dissociation; and
a solvent in which the halide salt is soluble;
wherein at least some of the halide salt is dissolved and at least some of the Lewis base is deprotonated;
subjecting the deposited precursor solution to thermal annealing to facilitate the formation of a lead halide intermediate δ phase; and
effecting solvent removal from the deposited precursor solution;
wherein the Lewis base, while deprotonated, coordinates with the lead in the precursor material during formation of the intermediate δ phase, thereby stabilizing it; and
wherein solvent removal results in the re-protonation of the Lewis base and the reformation of the halide salt.

11. The method of claim 10, wherein:
the thermal annealing of the deposited precursor solution is performed at a temperature less than 150 °C.

12. The method of claim 10, wherein:
the solvent removal step comprises subjecting the deposited precursor solution to thermal annealing at a higher temperature.

13. The method of claim 10, wherein:
the solvent removal step comprises dripping an anti-solvent onto the deposited solution.

14. The method of claim 10, wherein:
the solvent removal step is performed such that at least 95% of the solvent is removed in 15 minutes.

15. The method of claim 14, wherein:
the solvent removal step is performed at a temperature less than 150 °C.

16. A method of fabricating lead halide perovskites at temperatures less than 150 °C, the method comprising the steps of:
depositing a precursor solution on a substrate, the precursor solution comprising:
a lead halide precursor material;
semicarbazide hydrochloride (SECl) salt; and
a solvent in which the halide salt is soluble;
wherein at least some of the semicarbazide hydrochloride salt has decomposed into semicarbazide (SE) and hydrochloric acid (HCl);
subjecting the deposited precursor solution to thermal annealing, thereby facilitating the formation of a lead halide intermediate δ phase; and
effecting solvent removal from the deposited precursor solution;
wherein the semicarbazide coordinates with lead in the precursor material during formation of the intermediate δ phase, thereby stabilizing it; and
wherein solvent removal results in the the re-protonation of the semicarbazide and the reformation of semicarbazide hydrochloride salt.

17. The method of claim 16, wherein:
the lead halide precursor material comprises lead iodide-based material such as formamidinium lead iodide (FAPbI3).

18. The method of claim 16, wherein:
the solvent comprises at least one of dimethylformamide (DMF) and dimethyl sulfoxide (DMSO).

19. The method of claim 18, wherein:
the solvent comprises both DMF and DMSO;
the solvent removal step comprises performing anti-solvent dripping on the deposited precursor solution to remove at least some of the DMF; and
the solvent removal step further comprises subjecting the deposited precursor solution to thermal annealing to remove at least some of the DSMO.
